(19) United States
(12) Patent Application Publication
(10) Pub. No.: US 2024/0063114 A1
(43) Pub. Date: Feb. 22, 2024

(54) ANTIFUSES USING A FINFET ARCHITECTURE

(71) Applicant: Micron Technology, Inc., Boise, ID (US)

(72) Inventor: Si-Woo Lee, Boise, ID (US)

(21) Appl. No.: 17/891,523

(22) Filed: Aug. 19, 2022

(51) Int. Cl. H01L 23/525; H01L 29/78; H01L 29/66

(52) U.S. Cl. CPC H01L 23/5252; H01L 29/7851; H01L 29/66803

(57) ABSTRACT

A variety of applications can include an apparatus having one or more antifuses, where the antifuses are structured using components of a FinFET architecture. An antifuse can include a gate, multiple source/drain regions, and one or more fins separated from the gate by a dielectric and individually connected to selected ones of the multiple source/drain regions. The one or more fins connect to and can extend from its associated source/drain region to a terminal fin location under the gate.

### FIELD OF THE DISCLOSURE

Embodiments of the disclosure relate generally to electronic systems and, more specifically, to antifuses and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as antifuses of electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a top view of a representation of an example antifuse using a fin field effect transistor architecture for an integrated circuit, according to various embodiments.

FIG. 2 is a top view of a representation of another example antifuse using a fin field effect transistor architecture for an integrated circuit, according to various embodiments.

FIG. 3 is a top view of a representation of another example antifuse using a fin field effect transistor architecture for an integrated circuit, according to various embodiments.

FIG. 4 is a cross-sectional view of the antifuse of FIG. 3 along direction line A-A′, according to various embodiments.

FIG. 5 is a block diagram of features of an example memory device having antifuses using a fin field effect transistor architecture, according to various embodiments.

FIG. 6 is a schematic of an example memory device that can include the arrangement of the memory device of FIG. 5, according to various embodiments.

FIG. 7 is a flow diagram of features of an embodiment of an example method of forming an antifuse, according to various embodiments.

FIG. 8 is a block diagram illustrating an example of a machine that can be implemented with devices having antifuses using a fin field effect transistor architecture, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

An antifuse can be structured as a two-state element. In one state, the antifuse is basically a non-conductive element (a high resistance state) and, in the second state, the antifuse is a conductive element (a low resistance state). An antifuse can initially be in a non-conductive state and can be changed to a conductive state by applying an electric signal greater than a threshold for the antifuse. An antifuse provides a conductive path when activated. Prior to activation, the high resistance state can correspond to one binary state such as a zero. After activation, the low resistance state can correspond to the other binary state such as a one. Alternatively, logic can assign a zero to the low resistance state of the antifuse and a one to the high resistance state of the antifuse.

An antifuse can be structured as a metal-oxide-semiconductor field-effect transistor (MOSFET) that can be activated by application of a voltage between a gate and a source/drain of the transistor to a level that ruptures the gate dielectric of the transistor to generate a conductive path between the gate and the channel structure of the transistor below the gate dielectric. The gate dielectric can be structured with implants to provide a degraded gate dielectric, where the level of the degradation can be designed to meet a selected voltage for activating the antifuse. Reliability of such an antifuse is based on the ability to rupture the gate dielectric.

In various embodiments, an antifuse can be structured using components of a FinFET architecture, where fins are offset with respect to the source/drain regions of the FinFET architecture. A fin can be structured to connect to a source/drain region and extend from the source/region as in a FinFET architecture, where the end of the fin opposite the source/drain region can terminate under the gate of the FinFET architecture. The fin is separated from the gate by the gate dielectric of the FinFET architecture. The end of the fin, which is an effective fin tip, provides a location for increased electric field, which increases ability to rupture the gate dielectric. Arrangements of offset fins that terminate under the gate can lead to an enhanced rupture rate that provides increased reliability due to the enhanced failure rate. Efficient operation of the antifuse relies on the gate dielectric rupturing, that is, the gate dielectric fails as an electrical insulation region of relative high resistance between the gate and the channel structure in a FinFET architecture. The antifuse structured using components of a FinFET architecture can be implemented without additional special processing. In addition, activating the antifuse, structured using components of a FinFET architecture, can use lower voltage fusing due to the increased electric field that can be attained at the tip of the fin of the antifuse. To increase reliability, multiple fins can be used to increase the probability of gate dielectric rupture to generate a lower resistance path.

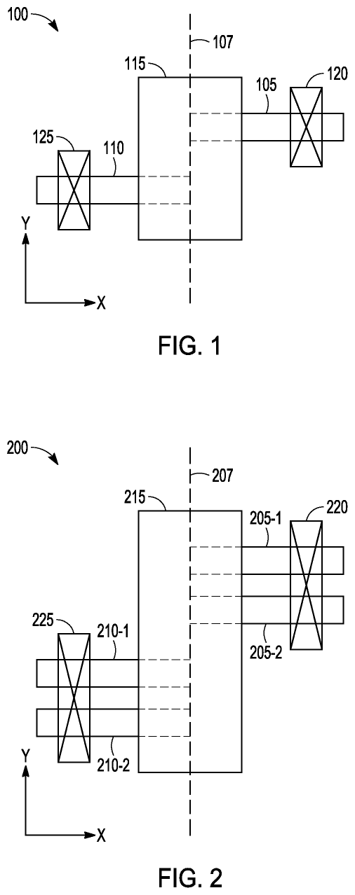

FIG. 1 is a top view of a representation of an example antifuse 100 using a FinFET architecture for an integrated circuit. Antifuse 100 can include a gate 115, a fin 105, a fin 110, a source/drain region 120, and a source/drain region 125. Fin 105 connects to source/drain region 120 and extends from source/drain region 120 to a location under gate 115. Fin 105 is separated from gate 115 by a dielectric, which is a gate dielectric in a FinFET architecture, though not shown in the top view of FIG. 1. Fin 110 connects to source/drain region 125 and extends from source/drain region 125 to a location under gate 115, different from the end location of fin 105. Fin 110 is also separated from gate 115 by a dielectric, which is a gate dielectric in a FinFET architecture, though not shown in the top view of FIG. 1. Fin 110 is offset from fin 105 relative to source/drain region 120 and source/drain region 125 such that fin 105 and fin 110 do not intersect. Unlike fins in a FinFET architecture, fin 105 does not connect to two source/drain regions and fin 110 does not connect to two source/drain regions. The ends of fins 105 and 110 under gate 115 can be located on a reference line 107 in the y-direction through gate 115. Alternatively, the ends of fins 105 and 110 under gate 115 can be located at different positions in the x-direction under gate 115. The reference line 107 can be centered in gate 115 or located at a different position in the x-direction in gate 115. The ends of fins 105 and 110 under gate 115 provide a location for increased electric field in activation of antifuse 100 due to the termination of the horizontal extent of fins 105 and 110.

The activation of antifuse 100 can be performed by applying voltage of sufficient magnitude between gate 115 and source/drain region 120 or between gate 115 and source/drain region 125. The activation voltage is a voltage sufficient to rupture a dielectric that is located between a fin and a gate to generate a lower resistance between the gate and the channel structure provided by the fin to generate a conductive path from a normally non-conductive path. The activation voltage can be based on relevant specifications of the components of antifuse 100 including, but not limited to, thicknesses and materials of the components. An activation is successful with the rupture of a dielectric between a gate and a fin and generation of a low resistance path (relative to a higher resistance provided by the unruptured dielectric). To increase reliability of activation, failure rate of the dielectric, where failure of the dielectric is rupture of the dielectric, can be increased. To increase the failure rate of a dielectric of antifuse 100, the activation voltage can be applied between gate 115 and both source/drain region 120 and source/drain region 125, which provides two sources of gate dielectric rupture as opposed to one source corresponding to the activation voltage applied to only one of the two source/drain regions.

The dielectric between fin 105 and gate 115 can be of the same composition as the dielectric between fin 110 and gate 115. The dielectrics between fins and the gate can be structured as one or more dielectric materials. The dielectrics between fins and the gate can be a high-k dielectrics. Herein, a high-k dielectric is a dielectric having a dielectric constant greater than 3.9, where 3.9 is a dielectric constant of silicon oxide. The dielectrics can include one or more of silicon oxide, silicon oxynitride, zirconium oxide, hafnium oxide, aluminum oxide, or a combination thereof. Other dielectric compositions can be used.

Source/drain regions, such as source/drain regions 120 and 125, in a FinFET architecture are transistor active areas. The source/drain regions are structured as p-type or n-type regions, which can be doped to provide conductive regions to which contacts ca be made to provide operational voltages. The source/drain regions can be structured as p+ or n+ regions. Fin 105 and fin 110 can be structured as semiconductor fins connected to source/drain region 120 and source/drain region 125, respectively. Fin 105 and fin 110 can be, but are not limited to, silicon fins. With contacts coupled to source/drain regions 120 and 125, voltages can be applied to fins 105 and 110. A contact to gate 115 allows control of a voltage to gate 115 with a different voltage to source/drain region 120 or source/drain region 125 to generate an electric field at the end tips of fin 105 or fin 110 to activate antifuse 100. In various embodiments, in operation a common voltage can be applied to contacts to both source/drain region 120 and source/drain region 125. Optionally, the contacts to source/drain region 120 and source/drain region 125 can be electrically wired together.

Gate 115 is a conductive component of antifuse 100. Gate 115 can be a metal gate. Gate 115 can include one or more of titanium nitride, tantalum nitride, tungsten, molybdenum, ruthenium, or a combination thereof. Other metallic compositions can be used as gate 115. A metallic composition is a metal or a composition of two or more elements such that the composition has electrical properties of a metal. A metallic composition can be structured having one or more metals and one or more non-metals.

FIG. 2 is a top view of a representation of an example antifuse 200 using components of a FinFET architecture for an integrated circuit. Antifuse 200 can include a gate 215, one pair of fins connected to a source/drain region 220, and another pair of fins connected to source/drain region 225. The pair of fins connected to source/drain region 220 includes fin 205-1 and 205-2. Fin 205-1 connects to source/drain region 220 and extends from source/drain region 220 to a location under gate 215. Fin 205-2 connects to source/drain region 220 and extends from source/drain region 220 to another location under gate 215. Fins 205-1 and 205-2 can be parallel to each other. Fin 205-1 is separated from gate 215 by a dielectric and fin 205-2 is separated from gate 215 by a dielectric, where the dielectrics on fins 205-1 and 205-2 (not shown in the top view of FIG. 2) can have the same dielectric composition. Alternatively, the dielectrics on fins 205-1 and 205-2 can have different dielectric compositions.

The pair of fins connected to source/drain region 225 includes fin 210-1 and 210-2. Fin 210-1 connects to source/drain region 225 and extends from source/drain region 225 to a location under gate 215. Fin 210-2 connects to source/drain region 225 and extends from source/drain region 225 to another location under gate 215. Fins 210-1 and 210-2 can be parallel to each other. Fins 210-1 and 210-2 can be parallel to fins 205-1 and 205-2. Fin 210-1 is separated from gate 215 by a dielectric and fin 210-2 is separated from gate 215 by a dielectric, where the dielectrics on fins 210-1 and 210-2 (not shown in the top view of FIG. 2) can have the same dielectric composition. Alternatively, the dielectrics on fins 210-1 and 210-2 can have different dielectric compositions. The dielectrics for fins 210-1 and 210-2 can be structured similar to the dielectrics for fins 205-1 and 205-2.

Fins 205-1 and 205-2 are offset from fins 210-1 and 210-2 relative to source/drain region 220 and source/drain region 225 such that fins 205-1 and 205-2 and fins 210-1 and 210-2 do not intersect. Each of fins 205-1 and 205-2 and each of fins 210-1 and 210-2 does not connect to two source/drain regions. The ends of fins 205-1, 205-2, 210-1, and 210-2 can be located on a reference line 207 in the y-direction through gate 215. Alternatively, the ends of fins 205-1, 205-2, 210-1, and 210-2 under gate 215 can be located at different positions in the x-direction under gate 115. The reference line 207 can be centered in gate 215 or located at a different position in the x-direction in gate 215. The ends of fins 205-1, 205-2, 210-1, and 210-2 under gate 215 provide a location for increased electric field in activation of antifuse 200 due to the termination of the horizontal extent of fins 205-1, 205-2, 210-1, and 210-2.

The activation of antifuse 200 can be performed by applying voltage of sufficient magnitude between gate 215 and source/drain region 220 or between gate 215 and source/drain region 225. The activation voltage can be based on relevant specifications of the components of antifuse 200 including, but not limited to, thicknesses and materials of the components. The specifications of the components of antifuse 200 can be selected from the set of specifications from which components of antifuse 100 can be selected.

With a contact coupled to source/drain region 220, the voltage applied to fin 205-1 is the same as the voltage applied to fin 205-2. With a contact coupled to source/drain region 225, the voltage applied to fin 210-1 is the same as the voltage applied to fin 210-2. A contact to gate 215 allows control of a voltage to gate 215 different from the voltage to source/drain region 220 or different from the voltage to source/drain region 225 to generate an electric field at the end tips of fins 205-1 and 205-2 or at the end tips of fins 210-1 and 210-2 to activate antifuse 200. The arrangement of multiple fins provides a mechanism for increased reliability. In various embodiments, a common voltage can be applied to contacts to both source/drain region 220 and source/drain region 225. Optionally, the contacts to source/drain region 220 and source/drain region 225 can be electrically wired together. Alternatively, antifuse 200 can be structured in an integrated circuit to operate source/drain region 220 with fins 205-1 and fins 205-2 as a separate unit from source/drain region 220 with fins 210-1 and fins 210-2.

Antifuse 200 of FIG. 2 can differ from antifuse 100 of FIG. 1 by the number of fins extending from source/drain regions. While the source/drain regions of antifuse 100 have one fin extending out to a terminal location under a gate, the source/drain regions of antifuse 200 have two fins extending out to a terminal location under a gate. If the number of fins increases, the antifuse failure drops from a given failure rate, F, to a failure rate of F squared. For example, with F equal to 100 ppm, increasing the number of fins, such as from one to two, drops the failure rate to 0.01 ppm. Depending on size specifications of the integrated circuit in which one or more antifuses are located, the number of fins from a source/drain region under a gate of the antifuse can be greater than two from each source/drain, or the number of fins from multiple source/drain regions can vary among the source/drains of the antifuse.

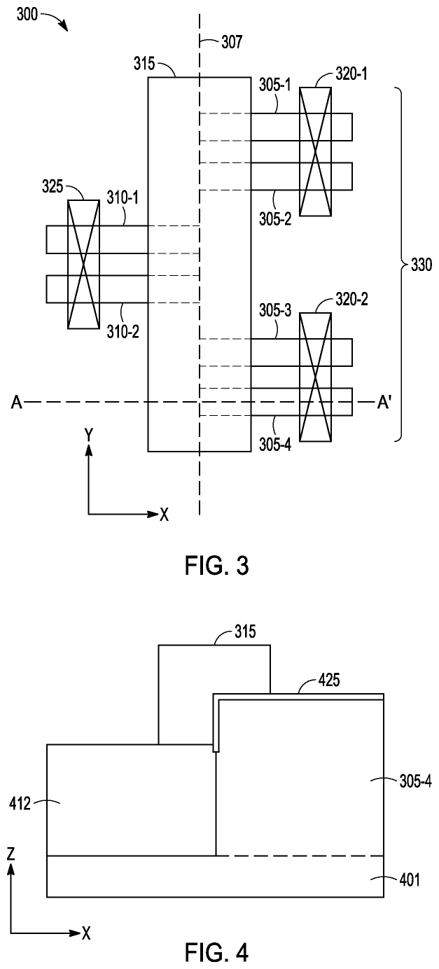

FIG. 3 is a top view of a representation of an example antifuse 300 using components of a FinFET architecture for an integrated circuit. Antifuse 300 can include a gate 315, a pair of fins connected to a source/drain region 320-1, a pair of fins connected to a source/drain region 320-2, and a pair of fins connected to source/drain region 325. The pair of fins connected to source/drain region 320-1 includes fins 305-1 and 305-2. Fin 305-1 connects to source/drain region 320-1 and extends from source/drain region 320-1 to a location under gate 315. Fin 305-2 connects to source/drain region 320-1 and extends from source/drain region 320-1 to another location under gate 315. Fins 305-1 and 305-2 can be parallel to each other. Fin 305-1 is separated from gate 315 by a dielectric and fin 305-2 is separated from gate 315 by a dielectric, where the dielectrics on fins 305-1 and 305-2 (not shown in the top view of FIG. 2) can have the same dielectric composition. Alternatively, the dielectrics on fins 305-1 and 305-2 can have different dielectric compositions.

The pair of fins connected to source/drain region 320-2 includes fin 305-3 and 305-4. Fin 305-3 connects to source/drain region 320-2 and extends from source/drain region 320-2 to a location under gate 315. Fin 305-4 connects to source/drain region 320-2 and extends from source/drain region 320-2 to another location under gate 315. Fins 305-3 and 305-4 can be parallel to each other. Fins 305-1 and 305-2 can be parallel to fins 305-3 and 305-4. Fin 305-3 is separated from gate 315 by a dielectric and fin 305-4 is separated from gate 315 by a dielectric, where the dielectrics on fins 305-3 and 305-4 (not shown in the top view of FIG. 3) can have the same dielectric composition. Alternatively, the dielectrics on fins 305-3 and 305-4 can have different dielectric compositions. The dielectrics for fins 305-3 and 305-4 can be structured similar to the dielectrics for fins 305-1 and 305-2.

The pair of fins connected to source/drain region 325 includes fin 310-1 and 310-2. Fin 310-1 connects to source/drain region 325 and extends from source/drain region 325 to a location under gate 315. Fin 310-2 connects to source/drain region 325 and extends from source/drain region 325 to another location under gate 315. Fins 310-1 and 310-2 can be parallel to each other. Fin 310-1 is separated from gate 315 by a dielectric and fin 310-2 is separated from gate 315 by a dielectric, where the dielectrics on fins 310-1 and 310-2 (not shown in the top view of FIG. 2) can have the same dielectric composition. Alternatively, the dielectrics on fins 310-1 and 310-2 can have different dielectric compositions. The dielectrics for fins 310-1 and 310-2 can be structured similar to the dielectrics for fins 305-1 and 305-2 or fins 305-3 and 305-4.

Fins 310-1 and 310-2 are offset from fins 305-1 and 305-2 and fins 305-3 and 305-4 relative to source/drain region 320-1, source/drain region 320-2, and source/drain region 325 such that fins 305-1 and 305-2, fins 305-3 and 305-4, and fins 210-1 and 210-2 do not intersect. Each of fins 305-1 and 305-2, each of fins 305-3 and 305-4, and each of fins 310-1 and 310-2 do not connect to two source/drain regions. The ends of fins 305-1, 305-2, 305-1, 305-2, 310-1, and 310-2 can be located on a reference line 307 in the y-direction through gate 315. Alternatively, the ends of fins 305-1, 305-2, 305-3, 305-4, 310-1, and 310-2 under gate 315 can be located at different positions in the x-direction under gate 315. The reference line 307 can be centered in gate 315 or located at a different position in the x-direction in gate 315. The ends of fins 305-1, 305-2, 305-3, 305-4, 310-1, and 310-2 under gate 315 provide a location for increased electric field in activation of antifuse 300 due to the termination of the horizontal extent of fins 305-1, 305-2, 305-3, 305-4, 310-1, and 310-2.

The activation of antifuse 300 can be performed by applying voltage of sufficient magnitude between gate 315 and source/drain region 320-1, between gate 315 and source/drain region 320-2, or between gate 315 and source/drain region 325. The activation voltage can be based on relevant specifications of the components of antifuse 300 including, but not limited to, thicknesses and materials of the components. The specifications of the components of antifuse 300 can be selected from the set of specifications from which components of antifuse 100 or antifuse 200 can be selected.

With a contact coupled to source/drain region 320-1, the voltage applied to fin 305-1 is the same as the voltage applied to fin 305-2. With a contact coupled to source/drain region 320-2, the voltage applied to fin 305-3 is the same as the voltage applied to fin 305-4. With a contact coupled to source/drain region 325, the voltage applied to fin 310-1 is the same as the voltage applied to fin 310-2. A contact to gate 315 allows control of a voltage to gate 315 different from the voltage to source/drain region 320-1, different from the voltage to source/drain region 320-2, or different from the voltage to source/drain region 325 to generate an electric field at the end tips of fins 305-1 and 305-2, at the end tips of fins 305-3 and 305-4, or at the end tips of fins 310-1 and 310-2 to activate antifuse 300. The arrangement of multiple fins provides a mechanism for increased reliability. In various embodiments, a common voltage can be applied to contacts to two or more of source/drain region 320-1, source/drain region 320-2, and source/drain region 325. Optionally, the contacts to source/drain region 320-1, source/drain region 320-2, and source/drain region 325 can be electrically wired together. Alternatively, antifuse 300 can be structured in an integrated circuit to operate each of source/drain region 320-1 with fins 305-1 and fins 305-2, source/drain region 320-2 with fins 305-3 and fins 305-4, and separate units from each other.

FIG. 4 shows a cross-sectional view along direction A-A′ of fin 305-4 of antifuse 300 of FIG. 3. A dielectric 425 is on and contacting fin 305-4. Dielectric 425 separates fin 305-4 from gate 315 along a top surface of fin 305-4 and along the side of fin 305-4 contacting a dielectric 412. Dielectric 412 is located above and on a substrate 401 from which fin 305-4 extends, where substrate 401 provides a platform for structuring the fins and other components of antifuse 300. Substrate 401 can be, but is not limited to, silicon substrate. Dielectric 412 provides separation of fin 305-4 from other conductive components of antifuse 300. FIG. 4 shows a corner at the intersection of the top end of fin 305-4 and the side of fin 305-4. The corner provides a location to generate an increased electric field to rupture dielectric 412. Though a sharp fin tip can provide a sharp corner to increase the local electric field for better rupture rate, the fin tip of fin 305-4 can have a shape different from a rectangular cuboid of fin 305-4. Cross-sectional views of other fins of antifuse 300 can illustrate similar structures.

Antifuses 100, 200, and 300 of FIGS. 1-4 illustrate embodiments of anifuses using components of a FinFET architectures. Various features of antifuses 100, 200, or 300 can be implemented in similar antifuse embodiments. One or more antifuses, as taught herein, can be structured with a gate, multiple source/drain regions, and one or more fins separated from the gate by a dielectric and individually connected to selected ones of the multiple source/drain regions, where the one or more fins connect to and extend from its associated source/drain region to a terminal fin location under the gate. Contacts to the gate and multiple source/drain regions can couple the one or more antifuses to a control circuitry for the integrated circuit in which the one or more antifuses are deployed.

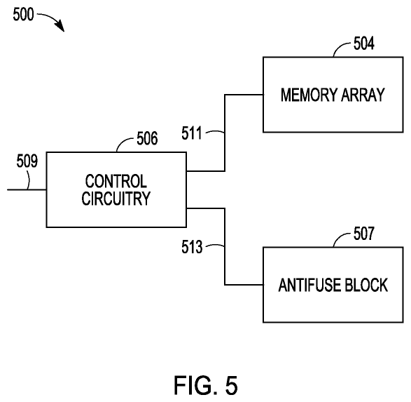

FIG. 5 is a block diagram of a memory device 500 that includes antifuses having components of a FinFET architecture. Memory device 500 can be structured as one or more integrated circuits in a memory die. Memory device 500 can include control circuitry 506, memory array 504, and antifuse block 507. Antifuse block 507 includes multiple antifuses structured as taught herein. An antifuse of antifuse block 507 can be structured with a gate, multiple source/drain regions, and one or more fins separated from the gate by a dielectric and individually connected to selected ones of the multiple source/drain regions, where the one or more fins connect to and extend from its associated source/drain region to a terminal fin location under the gate. Control circuitry 506 can operate, via communication path 511, with memory array 504 to read from, write to, ease, and maintain the memory cells of memory array 504. Maintenance of the memory cells can include repair or replacement of memory cells of groups of memory cells. In various approaches, detection of defects or failures in the memory array can be provided to control circuitry 506. Alternatively, detection of defects or failures in the memory array can be provided to control circuitry 506 via communication path 509 from a memory system device, such as a memory device controller operating with firmware of the memory system.

Control circuitry 506 can operate with antifuse block 507 to activate selected one or more antifuses of antifuse block 507. The successfully activated antifuse can change resistance between gate and fin of the antifuse to a significantly lower resistance. The changes in resistance can provide information, as a current via this changed path can be assigned a logic status. The logic status can be a binary status such as, but not limited to, a one. The logic status can be associated with one or memory cells of groups of memory cells in a redundant memory array associated with memory array 504. The redundant memory array can be a section of memory array 504 or another section in the memory die of memory device 500. Antifuses as taught herein can be used with different formats of memory devices. In addition, such antifuses can be implemented in integrated devices other than memory devices.

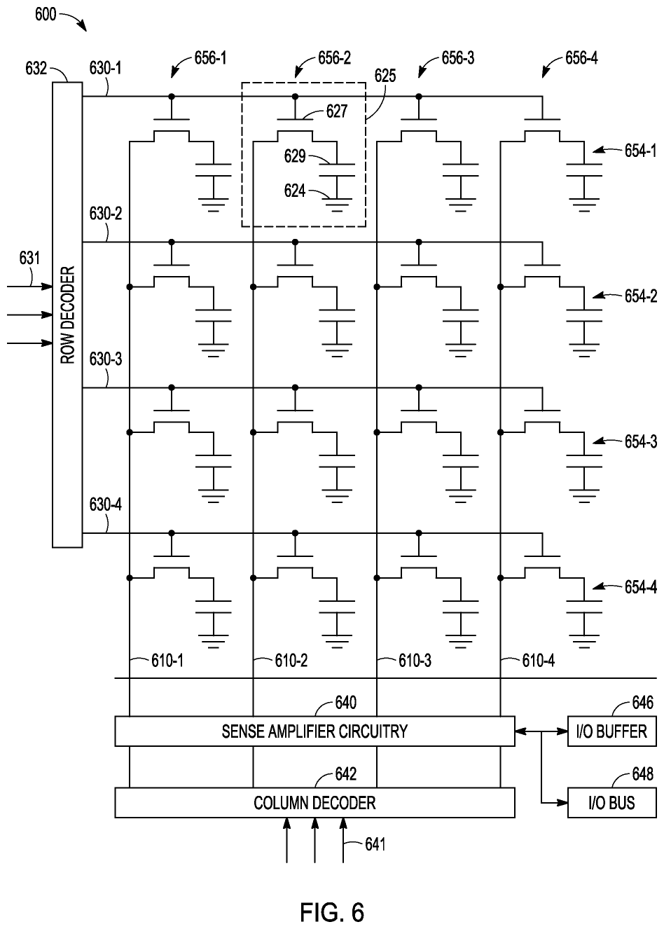

FIG. 6 is a schematic of an example DRAM memory device that can include the arrangement of the memory device 500 of FIG. 5. DRAM device 600 includes an array of memory cells 625 (only one being labeled in FIG. 6 for ease of presentation) arranged in rows 654-1, 654-2, 654-3, and 654-4 and columns 656-1, 656-2, 656-3, and 656-4. The array of memory cells can be implement as memory array of FIG. 5. For simplicity and ease of discussion, the array is shown in only two dimensions, but the array can be extended into the third dimension. Further, while only four rows 654-1, 654-2, 654-3, and 654-4 and four columns 656-1, 656-2, 656-3, and 656-4 of four memory cells are illustrated, DRAM devices like DRAM device 600 can have significantly more memory cells 625 (e.g., tens, hundreds, or thousands of memory cells) per row or per column.

Each memory cell 625 can include a single transistor 627 and a single capacitor 629, which is commonly referred to as a 1T1C (one-transistor-one capacitor cell). One plate of capacitor 629, which can be termed the “node plate,” is connected to the drain terminal of transistor 627, whereas the other plate of the capacitor 629 is connected to ground 624. Each capacitor 629 within the array of 1T1C cells 625 typically serves to store one bit of data, and the respective transistor 627 serves as an access device to write to or read from storage capacitor 629.

The transistor gate terminals within each row of rows 654-1, 654-2, 654-3, and 654-4 are portions of respective access lines 630-1, 630-2, 630-3, and 630-4 (alternatively referred to as “word lines”), and the transistor source terminals within each of columns 656-1, 656-2, 656-3, and 656-4 are electrically connected to respective digit lines 610-1, 610-2, 610-3, and 610-4 (alternatively referred to as “bit lines”). A row decoder 632 can selectively drive the individual access lines 630-1, 630-2, 630-3, and 630-4, responsive to row address signals 631 input to row decoder 632. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier circuitry 640, which can transfer bit values between the memory cells 625 of the selected row of the rows 654-1, 654-2, 654-3, and 654-4 and input/output buffers 646 (for write/read operations) or external input/output data buses 648.

A column decoder 642 responsive to column address signals 641 can select which of the memory cells 625 within the selected row is read out or written to. Alternatively, for read operations, the storage capacitors 629 within the selected row can be read out simultaneously and latched, and the column decoder 642 can then select which latch bits to connect to the output data bus 648. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 600 may be implemented as an integrated circuit within a package that includes pins for receiving supply voltages (e.g., to provide the source and gate voltages for the transistors 627) and signals (including data, address, and control signals). FIG. 6 depicts DRAM device 600 in simplified form to illustrate basic structural components, omitting many details of the memory cells 625 and associated access lines 630-1, 630-2, 630-3, and 630-4 and digit lines 610-1, 610-2, 610-3, and 610-4 as well as the peripheral circuitry. For example, in addition to the row decoder 632 and column decoder 642, sense amplifier circuitry 640, and buffers 646, DRAM device 600 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 654-1, 654-2, 654-3, and 654-4 and columns 656-1, 656-2, 656-3, and 656-4 of memory cells 625 are arranged along a single horizontal plane (i.e., a plane parallel to the layers) of the semiconductor substrate, e.g., in a rectangular lattice with mutually perpendicular horizontal access lines 630-1, 630-2, 630-3, and 630-4 and digit lines 610-1, 610-2, 610-3, and 610-4. In 3D DRAM arrays, the memory cells 625 are arranged in a 3D lattice that encompasses multiple vertically stacked horizontal planes corresponding to multiple device tiers of a multi-tier substrate assembly, with each device tier including multiple parallel rows of cells 625 whose transistor gate terminals are connected by horizontal access lines such as access lines 630-1, 630-2, 630-3, and 630-4. (A “device tier,” as used herein, can include multiple layers (or levels) of materials, but forms the components of memory devices of a single horizontal tier of memory cells.) Digit lines 610-1, 610-2, 610-3, and 610-4 extend vertically through all or at least a vertical portion of the multi-tier structure, and each of the digit lines 610-1, 610-2, 610-3, and 610-4 connects to the transistor source terminals of respective vertical columns 656-1, 656-2, 656-3, and 656-4 of associated memory cells 625 at the multiple device tiers. This 3D configuration of memory cells enables further increases in bit density compared with 2D arrays.

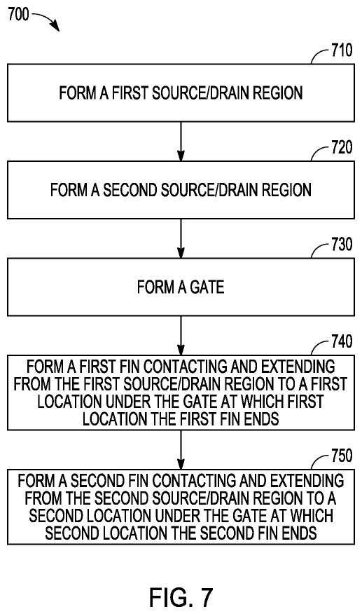

FIG. 7 is a flow diagram of features of an embodiment of an example method 700 of forming an antifuse. At 710, a first source/drain region is formed. The first source/drain region can be a p+ or n+ region. At 720, a second source/drain region is formed. The second source/drain region can be formed to mirror formation of the first source/drain region. At 730, a gate is formed. The gate of the antifuse can be formed as a metal gate. The gate can include one or more of titanium nitride, tantalum nitride, tungsten, molybdenum, ruthenium, or a combination thereof. Other metallic compositions can be formed as part of the gate. The gate can be formed with the first source/drain region and the second source/drain on opposite sides of the gate from each other.

At 740, a first fin is formed contacting and extending from the first source/drain region to a first location under the gate at which first location the first fin ends. The first fin is formed separated from the gate by a first dielectric. At 750, a second fin is formed contacting and extending from the second source/drain region to a second location under the gate at which second location the second fin ends. The second fin can be offset from the first fin such that the first fin and the second fin do not intersect. The second fin is formed separated from the gate by a second dielectric. The first dielectric and the second dielectric can be formed having a common composition. The common composition can include one or more of silicon oxide, silicon oxynitride, zirconium oxide, hafnium oxide, aluminum oxide, or combinations thereof. The common composition can be structured with one or more high-k dielectrics.

Variations of method 700 or methods similar to method 700 can include a number of different embodiments that can be combined depending on the application of such methods and/or the architecture of devices for which such methods are implemented. Such methods can include forming a third fin contacting and extending from the first source/drain region to a third location under the gate at which third location the third fin ends such that the third fin is parallel to the first fin. A third dielectric can be formed separating the third fin from the gate. A fourth fin can be formed contacting and extending from the second source/drain region to a fourth location under the gate at which fourth location the fourth fin ends such that the fourth fin is parallel to the second fin. A fourth dielectric can be formed separating the fourth fin from the gate. Variations of method 700 or methods similar to method 700 can also include forming a third source/drain region. A pair of fins can be formed contacting and extending from the third source/drain region to positions under the gate at which the pair of fins end, where the fins of the pair of fins offset from each other and from the first, second, third, and fourth fins such that the fins of the pair of fins do not intersect each of the first, second, third, and fourth fins. A dielectric can be formed separating each fin of the pair of fins separated from the gate.

Variations of method 700 or methods similar to method 700 can include forming the antifuse as an antifuse of a block of antifuses in a periphery to a memory array of a memory device, where the antifuses of the block have a common structure. Contacts can be formed to the antifuses of the block. Fins of the antifuses of the block can be formed such that the fins of each antifuse are staggered from each other, based on a margin value for the contacts.

In various embodiments, an antifuse can comprise components of a FinFET architecture with fins structured in an offset arrangement relative to source/drain regions. The antifuse can include a first source/drain region, a second source/drain region, a gate, and a first fin from the first source/drain region being offset from a second fin from the second source/drain region such that the first fin and the second fin do not intersect. The first fin contacts and extends from the first source/drain region to a first location under the gate at which first location the first fin ends. The first fin is separated from the gate by a first dielectric. The second fin contacts and extends from the second source/drain region to a second location under the gate at which second location the second fin ends. The second fin is separated from the gate by a second dielectric. Embodiments of such an antifuse can include additional structures based on the design using components of a FinFET architecture with offset fins. For example, each of the first fin and the second fin can be structured as a fin in a pair of fins, where the fins of each pair are arranged in parallel and have an end located under the gate rather than at another source/drain as in a conventional FinFET architecture. Antifuses can be structured with multiple source/drain regions and multiple pairs of fins that have ends under the gate and are offset from other pairs of fins relative to the multiple source/drain regions. In various embodiments, antifuses can be structured with multiple source/drain regions and multiple fins from one or more of the source/drain regions, where each of these fins have an end under the gate and are offset from other fins relative to the multiple source/drain regions.

Variations of such an antifuse, using components of a FinFET architecture, and its features, as taught herein, can include a number of different embodiments and features that can be combined depending on the application of such antifuses, the format of such antifuses, and/or the architecture in which such antifuses are implemented. Features of such antifuses can include a third fin contacting and extending from the first source/drain region to a third location under the gate at which third location the third fin ends, where the third fin is separated from the gate by a third dielectric. The third fin is structured parallel to the first fin. Variations can also include a fourth fin contacting and extending from the second source/drain region to a fourth location under the gate at which fourth location the fourth fin ends, where the fourth fin is separated from the gate by a fourth dielectric. The fourth fin can be parallel to the second fin.

Variations of such an antifuse, using components of a FinFET architecture, can include another source/drain region and another fin contacting and extending from this other source/drain region to another location under the gate at which location this other fin ends, where this other fin is separated from the gate by another dielectric and is offset from the first fin and offset from the second fin such that this other fin does not intersect the first fin and does not intersect the second fin.

Embodiments of antifuses having components of a FinFET architecture with fins structured in an offset arrangement relative to source/drain regions can be implemented in different electronic devices. Such antifuses can be used in memory devices, such as but not limited to, DRAM devices. These antifuses can structured in a periphery to the memory array of the memory devices, where the periphery can be in a common planar arrangement with the memory array or be situated at a level of the memory device that is under the level of the memory array.

In various embodiments, a memory device can comprise an array of memory cells and a block of antifuses, where the antifuses are structured for repair or replacement operations of a number of memory cells of the array. An antifuse of the block can be structured having components of a FinFET architecture with fins structured in an offset arrangement relative to source/drain regions. The antifuse can be structured similar to antifuses as taught herein. The antifuse can include a first source/drain region, a second source/drain region, a gate, and a first fin from the first source/drain region being offset from a second fin from the second source/drain region such that the first fin and the second fin do not intersect. The first fin contacts and extends from the first source/drain region to a first location under the gate at which first location the first fin ends. The first fin is separated from the gate by a first dielectric. The second fin contacts and extends from the second source/drain region to a second location under the gate at which second location the second fin ends. The second fin is separated from the gate by a second dielectric.

Variations of such a memory device and its features, as taught herein, can include a number of different embodiments and features that can be combined depending on the application of such memory devices, the format of such memory devices, and/or the architecture in which such memory devices are implemented. Features of such memory devices can include a third fin contacting and extending from the first source/drain region to a third location under the gate at which third location the third fin ends, where the third fin is parallel to the first fin, and a fourth fin contacting and extending from the second source/drain region to a fourth location under the gate at which fourth location the fourth fin ends, where the fourth fin is parallel to the second fin. The third fin is separated from the gate by a third dielectric and the fourth fin is separated from the gate by a fourth dielectric. Variations of the memory device can also include the antifuse structured to include a third source/drain region having a pair of fins contacting and extending from the third source/drain region to positions under the gate at which the pair of fins end, where the fins of the pair of fins are offset from each other and from the first, second, third, and fourth fins such that the fins of the pair of fins do not intersect each of the first, second, third, and fourth fins. Each fin of the pair of fins is separated from the gate by a dielectric.

Variations of such a memory device and its features can include the gate of the antifuse being a metal gate, where the first dielectric and the second dielectric can include one or more of silicon oxide, silicon oxynitride, zirconium oxide, hafnium oxide, aluminum oxide, or combinations thereof.

Variations of such a memory device and its features can include each of the antifuses of the block of antifuses having the same structure. The block can be structured with the antifuses in number being less than ten percent of a total number of memory cells of the array. The memory device can include control circuitry to activate an antifuse of the block of antifuses in response to a determination of a defect in the array of memory cells.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

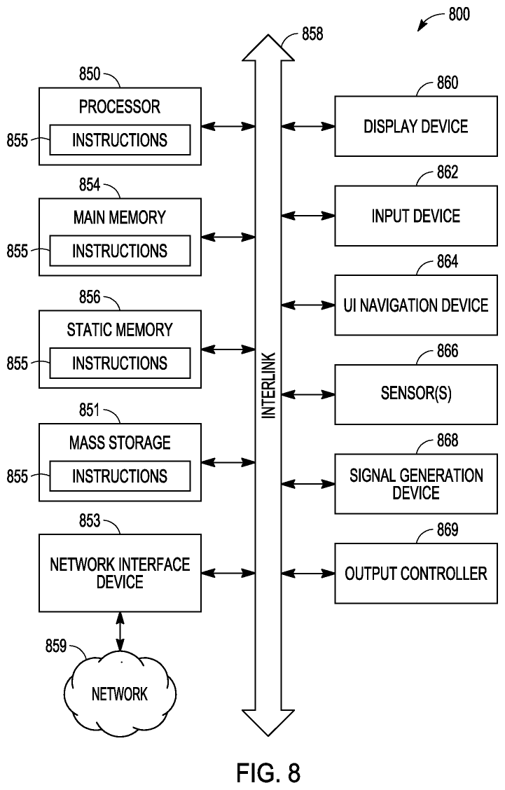

FIG. 8 illustrates a block diagram of an example machine 800 having one or more embodiments of an antifuse using components of a FinFET architecture as discussed herein. In alternative embodiments, machine 800 can operate as a standalone device or can be connected (e.g., networked) to other machines. In a networked deployment, machine 800 can operate in the capacity of a server machine, a client machine, or both in server-client network environments. In an example, machine 800 can act as a peer machine in peer-to-peer (P2P) (or other distributed) network environment. Machine 800 can be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies such as cloud computing, software as a service (SaaS), other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to store instructions of the specific operation. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components can be used in more than one member of more than one circuitry.

The machine 800 can include a hardware processor 850 (e.g., a CPU, a GPU, a hardware processor core, or any combination thereof), a main memory 854, and a static memory 856, some or all of which can communicate with each other via an interlink 858 (e.g., bus). Machine 800 can further include a display device 860, an input device 862, which can be an alphanumeric input device (e.g., a keyboard), and a user interface (UI) navigation device 864 (e.g., a mouse). In an example, display device 860, input device 862, and UI navigation device 864 can be a touch screen display. Machine 800 can additionally include a mass storage device (e.g., drive unit) 851, a network interface device 853, a signal generation device 868, and one or more sensors 866, such as a global positioning system (GPS) sensor, compass, accelerometer, or other sensor. Machine 800 can include an output controller 869, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 800 can include one or more machine-readable media on which is stored one or more sets of data structures or instructions 855 (e.g., software, microcode, or other type of instructions) embodying or utilized by machine 800 to perform any one or more of the techniques or functions for which machine 800 is designed. The instructions 855 can reside, completely or at least partially, within main memory 854, within static memory 856, or within hardware processor 850 during execution thereof by machine 800. In an example, one or any combination of hardware processor 850, main memory 854, static memory 856, or mass storage device 851 can constitute the machine-readable media on which is stored one or more sets of data structures or instructions. Various ones of hardware processor 850, main memory 854, static memory 856, or mass storage device 851 can include one or more antifuses using components of a FinFET architecture as discussed herein.

While an example machine-readable medium is illustrated as a single medium, the term “machine-readable medium” can include a single medium or multiple media (e.g., a centralized or distributed database, or associated caches and servers) configured to store instructions 855 or data. The term “machine-readable medium” can include any medium that is capable of storing instructions for execution by machine 800 and that cause machine 800 to perform any one or more of the techniques to which machine 800 is designed, or that is capable of storing data structures used by or associated with such instructions. Non-limiting machine-readable medium examples can include solid-state memories, optical media, and magnetic media. Specific examples of non-transitory machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 855 (e.g., software, programs, an operating system (OS), etc.) or other data stored on mass storage device 851 can be accessed by main memory 854 for use by hardware processor 850. Main memory 854 (e.g., DRAM) is typically fast, but volatile, and thus a different type of storage than mass storage device 851 (e.g., an SSD), which is suitable for long-term storage, including while in an “off” condition. Instructions 855 or data in use by a user or machine 800 are typically loaded in main memory 854 for use by hardware processor 850. When main memory 854 is full, virtual space from mass storage device 851 can be allocated to supplement main memory 854; however, because mass storage device 851 is typically slower than main memory 854, and write speeds are typically at least twice as slow as read speeds, use of virtual memory can greatly reduce user experience due to storage device latency (in contrast to main memory 854, e.g., DRAM). Further, use of mass storage device 851 for virtual memory can greatly reduce the usable lifespan of mass storage device 851.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 855 can further be transmitted or received over a network 859 using a transmission medium via signal generation device 868 or network interface device 853 utilizing any one of a number of transfer protocols (e.g., frame relay, Internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, signal generation device 868 or network interface device 853 can include one or more physical jacks (e.g., Ethernet, coaxial, or phone jacks) or one or more antennas to connect to network 859. In an example, signal generation device 868 or network interface device 853 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 800 or data to or from machine 800, and can include instrumentalities to propagate digital or analog communications signals to facilitate communication of such instructions, which instructions may be implemented by software or data.

The following are example embodiments of devices and methods, in accordance with the teachings herein.

An example antifuse 1 can comprise: a first source/drain region; a second source/drain region; a gate; a first fin contacting and extending from the first source/drain region to a first location under the gate at which first location the first fin ends, the first fin separated from the gate by a first dielectric; a second fin contacting and extending from the second source/drain region to a second location under the gate at which second location the second fin ends, the second fin separated from the gate by a second dielectric, the second fin being offset from the first fin such that the first fin and the second fin do not intersect.

An example antifuse 2 can include features of example antifuse 1 and can include a third fin contacting and extending from the first source/drain region to a third location under the gate at which third location the third fin ends, the third fin separated from the gate by a third dielectric, the third fin being parallel to the first fin.

An example antifuse 3 can include features of example antifuse 2 and any features of the preceding example antifuses and can include a fourth fin contacting and extending from the second source/drain region to a fourth location under the gate at which fourth location the fourth fin ends, the fourth fin separated from the gate by a fourth dielectric, the fourth fin being parallel to the second fin.

An example antifuse 4 can include features of any of the preceding example antifuses and can include a third source/drain region and a third fin, the third fin contacting and extending from the third source/drain region to a third location under the gate at which third location the third fin ends, the third fin separated from the gate by a third dielectric, the third fin offset from the first fin and offset from the second fin such that the third fin does not intersect the first fin and does not intersect the second fin.

An example antifuse 5 can include features of any of the preceding example antifuses and can include the first source/drain region and the second source/drain being on opposite sides of the gate from each other.

An example antifuse 6 can include features of any of the preceding example antifuses and can include the first dielectric and the second dielectric including a common composition.

An example antifuse 7 can include features of example antifuse 7 and any of the preceding example antifuses and can include the common composition including one or more of silicon oxide, silicon oxynitride, zirconium oxide, hafnium oxide, aluminum oxide, or a combination thereof.

An example antifuse 8 can include features of any of the preceding example antifuses and can include the gate being a metal gate.

An example antifuse 9 can include features of example antifuse 8 and any of the preceding example antifuses and can include the gate including one or more of titanium nitride, tantalum nitride, tungsten, molybdenum, ruthenium, or a combination thereof.

In an example antifuse 10, any of the antifuses of example antifuses 1 to 9 may include antifuses incorporated into an electronic memory apparatus further comprising a host processor and a communication bus extending between the host processor and the antifuse.

In an example antifuse 11, any of the antifuses of example antifuses 1 to 10 may be modified to include any structure presented in another of example antifuse 1 to 10.

In an example antifuse 12, any apparatus associated with the antifuses of example antifuses 1 to 11 may further include a machine-readable storage device configured to store instructions as a physical state, wherein the instructions may be used to perform one or more operations of the apparatus.

In an example antifuse 13, any of the antifuses of example antifuses 1 to 12 may be operated in accordance with any of the below example methods 1 to 9.

An example memory device 1 can comprise an array of memory cells and a block of antifuses, where the antifuses are structured for repair or replacement operations of a number of memory cells of the array. An antifuse of the block can include: a first source/drain region; a second source/drain region; a gate; a first fin contacting and extending from the first source/drain region to a first location under the gate at which first location the first fin ends, the first fin separated from the gate by a first dielectric; a second fin contacting and extending from the second source/drain region to a second location under the gate at which second location the second fin ends, the second fin separated from the gate by a second dielectric, the second fin being offset from the first fin such that the first fin and the second fin do not intersect.

An example memory device 2 can include features of example memory device 1 and can include a third fin contacting and extending from the first source/drain region to a third location under the gate at which third location the third fin ends, the third fin separated from the gate by a third dielectric, the third fin being parallel to the first fin; and a fourth fin contacting and extending from the second source/drain region to a fourth location under the gate at which fourth location the fourth fin ends, the fourth fin separated from the gate by a fourth dielectric, the fourth fin being parallel to the second fin.

An example memory device 3 can include features of memory device 2 and any features of the preceding example memory devices and can include a third source/drain region having a pair of fins contacting and extending from the third source/drain region to positions under the gate at which the pair of fins end, each of the pair of fins separated from the gate by a dielectric, the fins of the pair of fins offset from each other and from the first, second, third, and fourth fins such that the fins of the pair of fins do not intersect each of the first, second, third, and fourth fins.

An example memory device 4 can include features of any of the preceding example memory devices and can include the gate being a metal gate and the first dielectric and the second dielectric including one or more of silicon oxide, silicon oxynitride, zirconium oxide, hafnium oxide, aluminum oxide, or a combination thereof.

An example memory device 5 can include features of any of the preceding example memory devices and can include each of the antifuses of the block having a same structure and the block being structured with the antifuses in number being less than ten percent of a total number of memory cells of the array.

An example memory device 6 can include features of any of the preceding example memory devices and can include control circuitry to activate an antifuse of the block of antifuses in response to a determination of a defect in the array of memory cells.

In an example memory device 7, any of the memory devices of example memory devices 1 to 6 may include memory devices incorporated into an electronic memory apparatus further comprising a host processor and a communication bus extending between the host processor and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be formed in accordance with any of the methods of the below example methods 1 to 9.

An example method 1 can comprise forming an antifuse including: forming a first source/drain region; forming a second source/drain region; forming a gate; forming a first fin contacting and extending from the first source/drain region to a first location under the gate at which first location the first fin ends; forming a first dielectric separating the first fin from the gate; forming a second fin contacting and extending from the second source/drain region to a second location under the gate at which second location the second fin ends, the second fin being offset from the first fin such that the first fin and the second fin do not intersect; and forming a second dielectric separating the second fin from the gate.

An example method 2 can include features of example method 1 and can include forming a third fin contacting and extending from the first source/drain region to a third location under the gate at which third location the third fin ends such that the third fin is parallel to the first fin; forming a third dielectric separating the third fin from the gate; forming a fourth fin contacting and extending from the second source/drain region to a fourth location under the gate at which fourth location the fourth fin ends such that the fourth fin is parallel to the second fin; and forming a fourth dielectric separating the fourth fin from the gate.

An example method 3 can include features of example method 2 and any of the preceding example methods and can include forming a third source/drain region; forming a pair of fins contacting and extending from the third source/drain region to positions under the gate at which the pair of fins end, the fins of the pair of fins offset from each other and from the first, second, third, and fourth fins such that the fins of the pair of fins do not intersect each of the first, second, third, and fourth fins; and forming a dielectric separating each fin of the pair of fins from the gate.

An example method 4 can include features of any of the preceding example methods and can include forming the antifuse as an antifuse of a block of antifuses in a periphery to a memory array of a memory device, the antifuses having a common structure.

An example method 5 can include features of example method 4 and any of the preceding example methods and can include forming contacts to the antifuses of the block; and forming fins of the antifuses of the block such that the fins of each antifuse are staggered from each other based on a margin value for the contacts.

In an example method 6, any of the example methods 1 to 5 may be performed in forming an electronic memory apparatus further comprising a host processor and a communication bus extending between the host processor and the memory device.

In an example method 7, any of the example methods 1 to 6 may be modified to include operations set forth in any other of example methods 1 to 6.

In an example method 8, any of the example methods 1 to 7 may be implemented at least in part through use of instructions stored as a physical state in one or more machine-readable storage devices.

An example method 9 can include features of any of the preceding example methods 1 to 8 and can include performing functions associated with any features of example memory devices 1 to 8 and example example antifuses 1 to 13.

An example machine-readable storage device 1 storing instructions, that when executed by one or more processors, cause a machine to perform operations, can comprise instructions to perform functions associated with any features of example antifuses 1 to 13 and example memory devices 1 to 10 or perform methods associated with any features of example methods 1 to 9.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An antifuse comprising:
a first source/drain region;
a second source/drain region;
a gate;
a first fin contacting and extending from the first source/drain region to a first location under the gate at which first location the first fin ends, the first fin separated from the gate by a first dielectric; and
a second fin contacting and extending from the second source/drain region to a second location under the gate at which second location the second fin ends, the second fin separated from the gate by a second dielectric, the second fin being offset from the first fin such that the first fin and the second fin do not intersect.

2. The antifuse of claim 1, wherein the antifuse includes a third fin contacting and extending from the first source/drain region to a third location under the gate at which third location the third fin ends, the third fin separated from the gate by a third dielectric, the third fin being parallel to the first fin.

3. The antifuse of claim 2, wherein the antifuse includes a fourth fin contacting and extending from the second source/drain region to a fourth location under the gate at which fourth location the fourth fin ends, the fourth fin separated from the gate by a fourth dielectric, the fourth fin being parallel to the second fin.

4. The antifuse of claim 1, wherein the antifuse includes:
a third source/drain region; and
a third fin contacting and extending from the third source/drain region to a third location under the gate at which third location the third fin ends, the third fin separated from the gate by a third dielectric, the third fin offset from the first fin and offset from the second fin such that the third fin does not intersect the first fin and does not intersect the second fin.

5. The antifuse of claim 1, wherein the first source/drain region and the second source/drain are on opposite sides of the gate from each other.

6. The antifuse of claim 1, wherein the first dielectric and the second dielectric include a common composition.

7. The antifuse of claim 6, wherein the common composition includes one or more of silicon oxide, silicon oxynitride, zirconium oxide, hafnium oxide, aluminum oxide, or a combination thereof.

8. The antifuse of claim 1, wherein the gate is a metal gate.

9. The antifuse of claim 8, wherein the gate includes one or more of titanium nitride, tantalum nitride, tungsten, molybdenum, ruthenium, or a combination thereof.

10. A memory device comprising:
an array of memory cells; and
a block of antifuses, the antifuses structured for repair or replacement operations of a number of memory cells of the array, an antifuse of the block including:
a first source/drain region;
a second source/drain region;
a gate;
a first fin contacting and extending from the first source/drain region to a first location under the gate at which first location the first fin ends, the first fin separated from the gate by a first dielectric; and
a second fin contacting and extending from the second source/drain region to a second location under the gate at which second location the second fin ends, the second fin separated from the gate by a second dielectric, the second fin being offset from the first fin such that the first fin and the second fin do not intersect.

11. The memory device of claim 10, wherein the antifuse includes:
a third fin contacting and extending from the first source/drain region to a third location under the gate at which third location the third fin ends, the third fin separated from the gate by a third dielectric, the third fin being parallel to the first fin; and
a fourth fin contacting and extending from the second source/drain region to a fourth location under the gate at which fourth location the fourth fin ends, the fourth fin separated from the gate by a fourth dielectric, the fourth fin being parallel to the second fin.

12. The memory device of claim 11, wherein the antifuse includes a third source/drain region having a pair of fins contacting and extending from the third source/drain region to positions under the gate at which the pair of fins end, each of the pair of fins separated from the gate by a dielectric, the fins of the pair of fins offset from each other and from the first, second, third, and fourth fins such that the fins of the pair of fins do not intersect each of the first, second, third, and fourth fins.

13. The memory device of claim 10, wherein the gate is a metal gate and the first dielectric and the second dielectric include one or more of silicon oxide, silicon oxynitride, zirconium oxide, hafnium oxide, aluminum oxide, or a combination thereof.

14. The memory device of claim 10, wherein each of the antifuses of the block have a same structure and the block is structured with the antifuses in number being less than ten percent of a total number of memory cells of the array.

15. The memory device of claim 10, wherein the memory device includes control circuitry to activate an antifuse of the block of antifuses in response to a determination of a defect in the array of memory cells.

16. A method comprising:
forming an antifuse, including:
forming a first source/drain region;
forming a second source/drain region;
forming a gate;
forming a first fin contacting and extending from the first source/drain region to a first location under the gate at which first location the first fin ends;
forming a first dielectric separating the first fin from the gate;
forming a second fin contacting and extending from the second source/drain region to a second location under the gate at which second location the second fin ends, the second fin being offset from the first fin such that the first fin and the second fin do not intersect; and
forming a second dielectric separating the second fin from the gate.

17. The method of claim 16, wherein the method includes:
forming a third fin contacting and extending from the first source/drain region to a third location under the gate at which third location the third fin ends such that the third fin is parallel to the first fin;
forming a third dielectric separating the third fin from the gate;
forming a fourth fin contacting and extending from the second source/drain region to a fourth location under the gate at which fourth location the fourth fin ends such that the fourth fin is parallel to the second fin; and
forming a fourth dielectric separating the fourth fin from the gate.

18. The method of claim 17, wherein the method includes:
forming a third source/drain region;
forming a pair of fins contacting and extending from the third source/drain region to positions under the gate at which the pair of fins end, the fins of the pair of fins offset from each other and from the first, second, third, and fourth fins such that the fins of the pair of fins do not intersect each of the first, second, third, and fourth fins; and
forming a dielectric separating each fin of the pair of fins from the gate.

19. The method of claim 16, wherein the method includes forming the antifuse as an antifuse of a block of antifuses in a periphery to a memory array of a memory device, the antifuses having a common structure.

20. The method of claim 19, wherein the method includes:
forming contacts to the antifuses of the block; and
forming fins of the antifuses of the block such that the fins of each antifuse are staggered from each other based on a margin value for the contacts.
